(19) United States
(12) Patent Application Publication
(10) Pub. No.: US 2024/0401187 A1
(43) Pub. Date: Dec. 5, 2024

(54) METHOD FOR PRODUCING A COATED PERFORATED STEEL STRIP

(71) Applicant: voestalpine Stahl GmbH, Linz (AT)

(72) Inventors: Wolfgang Burgstaller, Linz (AT); Siegfried Kolnberger, Pasching (AT); Arnold Kapellner, Linz (AT); Peter Pentschev, Engerwitzdorf (AT)

(21) Appl. No.: 18/799,720

(22) Filed: Aug. 9, 2024

Related U.S. Application Data
(63) Continuation of application No. PCT/EP23/53339, filed on Feb. 10, 2023.

(30) Foreign Application Priority Data
Feb. 10, 2022 (DE) 10 2022 103 180.2

(51) Int. Cl. C23C 14/56; C23C 14/02; C23C 14/22

(52) U.S. Cl. CPC C23C 14/562; C23C 14/028; C23C 14/223

(57) ABSTRACT

The invention relates to a method for producing perforated steel strips with a metallic coating, wherein metal strips and in particular sheet steel strips with a perforation or hole pattern are fed to and guided through a coating device in which the sheet metal strip is continuously PVD-coated with a vapor flow.

### CROSS-REFERENCE TO RELATED APPLICATIONS

This application is a Continuation of and claims benefit of priority to International Application No. PCT/EP23/53329, filed on Feb. 10, 2023, which claims the benefit of DE Application No. 10 2022 103 180.2, filed on Feb. 10, 2022. The entire contents of each are hereby incorporated by reference.

### BACKGROUND OF THE DISCLOSED SUBJECT MATTER

### Field of the Disclosed Subject Matter

The disclosed subject matter relates to a method for producing coated, perforated steel strip and the steel strip that is produced in this way.

### DESCRIPTION OF RELATED ART

It is known to provide steel strip with a perforation, in particular with a hole pattern, before further processing. The holes can be circular, but can also be any other shape so that a hole pattern or grid is produced.

One use for such perforated steel strips is, for example, cladding for noise barriers and the like. Since such noise barriers, but also other outdoor applications, usually need to be protected from corrosion, steel sheets with an appropriate corrosion protection coating are often used for this purpose, the most commonly used corrosion protection coating being a zinc coating. Such zinc coatings are known and are applied either using the electrogalvanization method, which is for applying pure zinc coatings, or using the hot-dip galvanization process. In the hot-dip galvanizing process, alloys are usually used that are based on zinc but have admixtures of aluminum, magnesium, or other elements.

In the production of corrosion-protected perforated sheets, strip-galvanized material is usually used, which is either electrolytically or hot-dip galvanized and then punched to produce the intended hole pattern.

The disadvantage here is that, depending on the sheet thickness, there is less corrosion protection—or none at all—on the punched surfaces. It is also known to punch ungalvanized strip material, process it into sheet bars and then galvanize them as piece goods; the disadvantage here, though, is that starting from a defined minimum opening cross-section, perforations can become clogged. In addition, the sequence of punching, sheet bar production, and piece galvanizing is expensive and time-consuming.

Such ungalvanized sheets with a perforated pattern can also conceivably be continuously coated using the Sendzimir process, but this type of hot-dip galvanizing is associated with major problems since it is only feasible with relatively large hole diameters of greater than 8 mm, and hot-dip galvanizing usually involves the use of stripping nozzles after the passage through the zinc bath, which use compressed air to strip the adhering excess zinc down to the desired coating thickness. With perforated strip, this treatment causes turbulence in the region of the holes, which on the one hand results in an uneven coating thickness and on the other hand negatively affects the opposing nozzles.

Similar disadvantages are also to be expected with the well-known Gravitel process. The holes in the strip make the current density and therefore the coating thickness uneven and dendrites form along the edges.

A PVD coating process for metal grids is known from GB 1325933 A1. In this case, a strip is guided horizontally through a PVD coating chamber. In this case, the walls of the coating chamber extend very close to the strip in order to minimize losses.

The coating material is vaporized only on the bottom, but the strip should be homogeneously and uniformly coated on the top and bottom. This can only be achieved, though, if the hole area/total area ratio is ≲1 (in the projection perpendicular to the strip), i.e. the holes/recesses make up the majority. This requires a hole area/total area ratio of ≥0.8. It is also stated that electrochemical pre-cleaning prior to vacuum coating is sufficient. The thickness of the coating is to be regulated by the strip speed or the strip temperature. Both methods have clear weaknesses and limit the coating possibilities. For thicker coatings, it is therefore necessary to reduce the strip speed, which also reduces the productivity of the process. If the strip temperature changes, then the coating formation (morphology) changes, the coating adhesion deteriorates, and a higher strip temperature leads to other process-related problems.

A PVD process for applying pyrolytic carbon to carbon structures is known from DE 2526036 C2.

### BRIEF DESCRIPTION OF THE DRAWINGS

A detailed description of various aspects, features, and embodiments of the subject matter described herein is provided with reference to the accompanying drawings, which are briefly described below. The drawings are illustrative and are not necessarily drawn to scale, with some components and features being exaggerated for clarity. The drawings illustrate various aspects and features of the present subject matter and may illustrate one or more embodiment(s) or example(s) of the present subject matter in whole or in part.

FIG. 1 shows a schematic depiction of a hole pattern.

FIG. 2 shows possible embodiments of hole patterns.

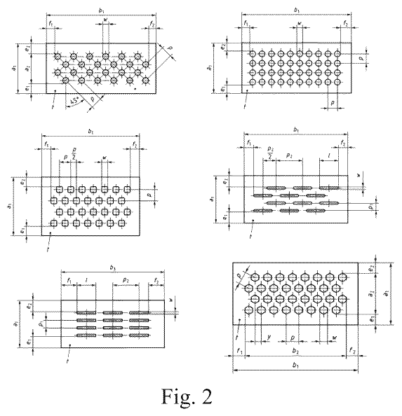

FIG. 3 shows a very schematic depiction of a coating chamber.

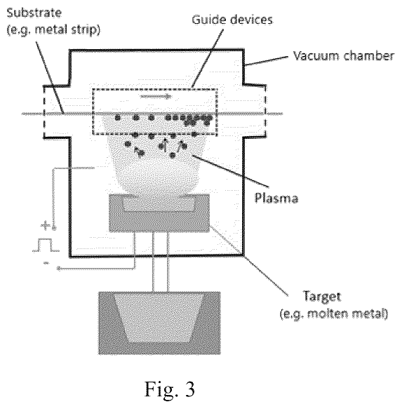

### DETAILED DESCRIPTION OF AN EXEMPLARY EMBODIMENT

Reference will now be made in detail to exemplary embodiments of the disclosed subject matter, an example of which is illustrated in the accompanying drawings. The method and corresponding steps of the disclosed subject matter will be described in conjunction with the detailed description of the system.

The object of the disclosed subject matter is to create a method for producing coated, perforated steel strips, which in particular enables corrosion protection even in the region of the edges and lateral surfaces of the holes.

The object is attained with a method having the features of claim 1.

Advantageous modifications are characterized in the dependent claims thereof.

The inventors have realized that a uniform distribution of the coating, made of zinc or zinc alloys and possibly other metals, is necessary, particularly for coating the punched edges and punched surfaces. The aim is to achieve minimal coating thickness deviations and a good surface finish combined with outstanding coating quality.

The object is attained with a method in which a perforated steel strip—a term that also includes expanded metal or long sheet bars—is coated in a PVD coating chamber using a PVD process. It has been discovered that by using a plasma evaporator, the particle density in the PVD chamber can be adjusted by adapting the plasma parameters for the coating of the perforated strip, wherein the particle flow is a function of the metal vapor density and the quotient (coating thickness on the punched surface)/(average coating thickness of the unpunched area) can be from 0.4 to 1.2.

According to the disclosed subject matter, it has been discovered that a plasma evaporator enables an easily controllable evaporation rate and thus a high metal vapor density, wherein the particles have a high kinetic energy so that this combination makes it possible to achieve a uniform and efficient coating of the punched surfaces and punched edges in a continuous process.

It has been discovered that both a horizontal strip travel through a PVD chamber and a vertical strip travel through a PVD chamber are possible.

With vertical strip travel, the method can be carried out in two stages so that the strip is first guided in one direction, for example upward, then deflected outside the coating chamber and subsequently guided downward in order to achieve symmetrical coating of both the punched and unpunched surfaces.

In addition, guide devices can be provided that regulate and direct the vapor flow, e.g. by means of guide plates, in order to avoid unfavorable coating thickness distributions.

In addition, an electrical potential difference in the range from 10 to 500 volts relative to the chamber wall can be applied to the substrate, e.g. the metal strip, via an external electrical circuit so that the local vapor flow can be influenced specifically in the region around the substrate to be coated.

The total surface area of the perforated plate, the desired average coating thickness, and the evaporation enthalpies of the coating materials result in a plasma power proportional to the strip speed, which can be adjusted accordingly.

A hole pattern or perforation as defined by the disclosed subject matter can comprise a wide variety of patterns that recur like a repeating pattern as well as regions that are not perforated longitudinally and/or transversely to the strip direction, which are provided, for example, for mechanical requirements (stability, rigidity) or for subsequent processing operations (e.g. bending).

A correspondingly perforated metal strip can be produced in a separate system and then delivered to the coating system or alternatively can be produced in a continuous inline process in a punching system upstream of the coating system.

The PVD coating according to the disclosed subject matter enables very efficient coating of perforated steel strip, permitting achievement of a corrosion protection of the punched surface. Another advantage here is that the punching waste can also be returned directly to the manufacturing plant for reuse without having to remove an existing coating before the reuse.

In addition, it is possible to use coating materials that are difficult or impossible to deposit with hot-dip galvanization or electrolytic galvanization since the PVD process generally allows for a wider range of coating materials.

It has also been discovered that a wide range of possible coating thicknesses from 0.1 μm to around 20 μm, for example, can be achieved with a simultaneously optimal coating of the punched edge. In addition, the coating thickness can be regulated via the strip width, the two sides of the strip can be coated with different thicknesses and different materials and, depending on the system configuration, it is also possible to produce multi-layer coatings.

The method according to the disclosed subject matter involves acting on both sides of a strip with a vapor flow in order to coat it on both sides or acting on one side with a vapor flow in order to coat only one side.

The ratio of the hole area to the total projected area can be selected to be less than 0.7, in particular less than 0.6, and especially less than 0.5 so that for a hexagonal hole pattern with a hole spacing of 7 mm and a hole radius of 2.5 mm in the projection, for example, the ratio of hole area to total area is 0.46.

In order to achieve a uniform coating, the chamber walls or the evaporator must be at least ten times the strip thickness away from the strip or alternatively, the above-mentioned hole area ratios must be maintained.

According to the disclosed subject matter, a vacuum-based pretreatment by means of plasma is carried out prior to the coating in a vacuum, regardless of any previously performed chemical pre-cleaning of the substrate.

According to the disclosed subject matter, the coating thickness is controlled by the plasma power of the evaporator, wherein both the strip speed and the strip temperature should be kept as constant as possible. The plasma power can be adjusted within very short time intervals and in particular within seconds and even faster.

How quickly the coating thickness can be changed in the longitudinal direction of the strip is limited essentially by the length of the coating chamber and the strip speed. In order to coat the strip evenly on the top and bottom, guide devices are used to coat both sides evenly with an evaporator positioned underneath in the case of a horizontal strip travel or with symmetrically arranged evaporators on both sides in the case of a vertical strip travel.

The disclosed subject matter therefore relates to a method for producing perforated steel strips with a metallic coating, wherein metal strips and in particular sheet steel strips with a perforation or hole pattern are fed to and guided through a coating device in which the sheet metal strip is continuously PVD-coated with a metal vapor flow.

In one embodiment, the metal strip has a sheet metal thickness of 0.3 mm to 2.5 mm. The advantage here is that, on the one hand, sufficient mechanical rigidity and stability can be ensured and, in addition, a reliably uniform coating is achieved with such thicknesses. Above 2.5 mm, there is a risk of uneven coating in the walls and along the edges.

In one embodiment, the strip is coated with one or more layers, wherein the layers of the coating consist of one, several, or all of the group metals, oxides, carbides, nitrides, and carbonitrides. The desired coatings or layers can thus advantageously be produced by means of PVD according to the desired application area or corrosion protection.

In one embodiment, the two sides of the strip are coated with the same or different coatings. In one embodiment, the two sides of the strip are coated with the same or different coatings. The advantage here is that for outdoor applications, the weather side can be provided with an increased layer thickness, for example. Alternatively, for indoor applications or desired glued or welded joints, for example, one side of the strip can be coated with easily welded/glued layers.

In one embodiment, the strip is coated with one, several, or all of the group zinc, magnesium, manganese, copper, chromium, aluminum, titanium, silicon, alloys with these elements, or alloys composed of these elements as main constituents. As defined by the disclosed subject matter, a main constituent means that the element makes up the largest share of the coating alloy, preferably >50%.

In one embodiment, the coating thickness of the PVD coating is 20 nm to 100 μm, preferably 100 nm to 50 μm, per side surface of the strip. The advantage here is that thick coatings can also be deposited to meet high corrosion protection requirements, particularly in the construction sector. A further advantage is that comparatively very thin coatings can be deposited and outstanding adhesion can be achieved without hardness loss, distortion, or changes to the microstructure of the base material.

In one embodiment, the coating thickness ratio of the coating of the strip side surface to that of the walls of the perforations is between 0.4 and 1.2, preferably between 0.6 and 0.9. The advantage here is that such a ratio is absolutely sufficient for good corrosion protection since the corrosive attack starts at the edges and does not initially occur in the middle of the wall. The inventors have therefore discovered that sufficient protection can already be achieved with a coating thickness ratio of around 0.4.

In one embodiment, the particle flow in the coating chamber is deflected onto the strip by means of guide devices.

In one embodiment, the guide devices are mechanical guide plates or electromagnetic guide devices.

In one embodiment, the coating thickness is measured and the guide devices are controlled in such a way that the desired coating thickness and coating thickness distribution are achieved.

In one embodiment, the distance between the walls of the coating chamber and the sheet is set so that it corresponds to 10 to 10,000 times, in particular 100 to 2,500 times, the thickness of the sheet. The advantage here is that the comparatively large distance means that the vapor flow can even out and the coating can therefore be deposited as homogeneously as possible.

In one embodiment, the distance between the guide devices and the sheet is set to 0.005 to 1 times, in particular 0.01 to 0.7 times, the sheet strip width. The sheet strip width can be between 500 mm and 2000 mm. The advantage here is that the relatively large distance from the guide devices means that the vapor flow hits the strip in a homogenized manner.

In one embodiment, the metal strip is continuously punched or perforated to produce the desired hole pattern and is then PVD-coated in a continuous inline process.

In this case, it is advantageously possible to provide an inline process, in particular already at the steel plant, wherein the metal strip is first punched or perforated continuously to produce the desired hole pattern. The strip can then be fed to a pre-treatment station for cleaning and/or pickling. In particular, the edges of the holes can also be treated in this case, for example by sandblasting. At this point, the strip can travel into the coating process, where it is then PVD-coated in a continuous inline process.

The inline process has several advantages. First, the punching waste is produced before the coating process. The uncoated punching waste can be reused directly as steel scrap in the steel plant. The transportation routes are also short. Another advantage of the inline process is that the surfaces produced are less aged. On the one hand, this eliminates the need for freeing the uncoated metal sheet of corrosion products that are produced during storage and/or transportation. In addition, the pre-treatment of slightly oxidized or non-corroded surfaces can be carried out in a comparatively more efficient way.

In one embodiment, the strip is guided horizontally and/or vertically through the coating chamber.

In one embodiment, in the case of vertical strip travel, the method is carried out as a multi-stage method in which the strip travels through at least twice, namely at least once upward and at least once downward. The advantage here is that both sides of the strip can be subjected to comparable coating conditions and therefore comparable and reproducible properties for the coating can be achieved on both sides.

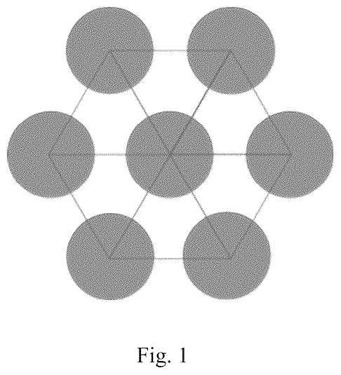

FIG. 1 shows a hexagonal hole pattern. For a hole spacing a=7 mm, a hole radius r=2.5 mm, and a sheet thickness of 0.9 mm, for example, the ratio of coated area F including the hole walls compared to the area F₀ of a sample without holes is approx. 70%, as expressed in the following equation:

$$\frac{F}{{F}_{0}} = \frac{{a}^{2} \frac{\sqrt{3}}{4} - {r}^{2} \frac{π}{2} + r π \frac{s}{2}}{{a}^{2} \frac{\sqrt{3}}{4}} \approx 0.704$$

The smallest cross-section of the punched sheet in relation to the cross-section of the unpunched sheet is (a−2r)/a, i.e. 2/7.

FIG. 1 shows a schematic depiction of a typical hole pattern. The hole structure is honeycomb-shaped with a hole spacing a=7 mm, a hole radius r=5 mm, and a sheet thickness s=0.9 mm.

A perforated sheet of this kind is fed into a PVD system with a corresponding coating chamber. The coating chamber in this case is embodied with airlocks so that the strip can be fed in and out without negatively changing the pressure conditions inside the coating chamber.

The perforated strip is coated by controlling the particle density in the coating chamber by means of defined plasma parameters. The particle flow in this case is a function of the metal vapor density, wherein the following applies to the sheet, for example

$$\frac{average coating thickness ( lateral surface of stamped region )}{average coating thickness ( surface of unstamped region )} = 0.6 to 0.9$$

The plasma evaporator produces a high vapor density with good controllability and the particles have a high kinetic energy. The combination of these two enables efficient punched surface coating in a continuous process.

With vertical strip travel, the method can be carried out as a two-stage method (strip traveling upward and downward) in order to achieve a symmetrical coating of the entire strip surface including the punched surfaces; this also depends on the design of the evaporator.

The coating chamber can be equipped with guide devices for guiding or distributing and controlling the particle flow. These can be guide plates or electromagnetic guide devices. These are used to regulate the local vapor flow.

Corresponding measurements can be performed on the coated sheets emerging from the vapor deposition chamber and fed back to the guide devices so that they achieve a desired coating thickness or coating thickness distribution.

Applying an electrical potential difference to the substrate relative to the chamber wall can also have an effect on the local vapor flow, especially in the region around the substrate to be coated.

It is comparatively easy to control the evaporator or the evaporator capacity by calculating the condensation heat for a certain amount of material. Since the total surface area of the perforated plate, the strip speed, and the desired average coating thickness are known as input parameters, the evaporator capacity can be easily determined based on the condensation heat.

The method according to the invention enables an efficient coating of perforated steel strip. For example, a zinc coating with uniform corrosion protection of the punched surface can be achieved. Another advantage is that the resulting uncoated punching waste can be conveyed directly back to the production of the perforated steel strip and reused for steel production in the plant without further processing.

In addition, depending on the coating material selected, a very wide range of possible coating thicknesses ranging from 0.1 μm to around 20 μm can be achieved.

The coating thickness can also be regulated across the strip width, particularly by means of the guide devices. It is also possible to deposit vapor composed of different materials on the two sides of the strip.

The coating process also makes it possible to apply multiple layers of different coating materials without a lot of effort.

While the disclosed subject matter is described herein in terms of certain preferred embodiments, those skilled in the art will recognize that various modifications and improvements may be made to the disclosed subject matter without departing from the scope thereof. Moreover, although individual features of one embodiment of the disclosed subject matter may be discussed herein or shown in the drawings of the one embodiment and not in other embodiments, it should be apparent that individual features of one embodiment may be combined with one or more features of another embodiment or features from a plurality of embodiments.

In addition to the specific embodiments claimed below, the disclosed subject matter is also directed to other embodiments having any other possible combination of the dependent features claimed below and those disclosed above. As such, the particular features presented in the dependent claims and disclosed above can be combined with each other in other manners within the scope of the disclosed subject matter such that the disclosed subject matter should be recognized as also specifically directed to other embodiments having any other possible combinations. Thus, the foregoing description of specific embodiments of the disclosed subject matter has been presented for purposes of illustration and description. It is not intended to be exhaustive or to limit the disclosed subject matter to those embodiments disclosed.

It will be apparent to those skilled in the art that various modifications and variations can be made in the method and system of the disclosed subject matter without departing from the spirit or scope of the disclosed subject matter. Thus, it is intended that the disclosed subject matter include modifications and variations that are within the scope of the appended claims and their equivalent

1. A method for producing perforated steel strips with a metallic coating, wherein metal strips and in particular sheet steel strips with a perforation or hole pattern are fed to and guided through a coating device in which the sheet metal strip is continuously PVD-coated with a vapor flow.

2. The method according to claim 1, characterized in that the strip has a sheet metal thickness of 0.3 mm to 2.5 mm.

3. The method according to claim 1, characterized in that the strip is coated with one or more layers, wherein the layers of the coating consist of one, several, or all of the group metals, oxides, carbides, nitrides, and carbonitrides.

4. The method according to claim 1, characterized in that the two sides of the strip are coated with the same or different coating materials and/or coating thicknesses.

5. The method according to claim 1, characterized in that the strip is coated with one, several, or all of the group zinc, magnesium, manganese, copper, chromium, aluminum, titanium, silicon, alloys with these elements, or alloys composed of these elements as main constituents.

6. The method according to claim 1, characterized in that the coating thickness of the PVD coating is 20 nm to 100 μm, preferably 100 nm to 50 μm, per side surface of the strip.

7. The method according to claim 1, characterized in that the coating thickness ratio of the coating of the strip side surface to that of the walls of the perforations is between 0.4 and 1.2, preferably between 0.6 and 0.9.

8. The method according to claim 1, characterized in that the particle flow in the coating chamber is deflected onto the strip by means of guide devices.

9. The method according to claim 1, characterized in that the guide devices are mechanical guide plates or electromagnetic guide devices.

10. The method according to claim 1, characterized in that the coating thickness is measured and the guide devices are controlled in such a way that a desired coating thickness and coating thickness distribution are achieved.

11. The method according to claim 1, characterized in that the distance between the walls of the coating chamber and the sheet is set so that it corresponds to 10 to 10,000 times, in particular 100 to 2,500 times, the thickness of the sheet.

12. The method according to claim 1, characterized in that the distance between the guide devices and the sheet is set to 0.005 to 1 times, in particular 0.01 to 0.75 times, the sheet strip width.

13. The method according to claim 1, characterized in that the metal strip is continuously punched or perforated to produce the desired hole pattern and is then PVD-coated in a continuous inline process.

14. The method according to claim 1, characterized in that the strip is guided horizontally and/or vertically through the coating chamber.

15. The method according to claim 14, characterized in that in the case of vertical strip travel, the method is carried out as a multi-stage method in which the strip travels through at least twice, namely at least once upward and at least once downward.

16. A perforated strip with a metallic coating, characterized in that the coating thickness ratio of the coating of the strip side surface to that of the walls of the perforations is between 0.4 and 1.2, preferably between 0.6 and 0.9.
